(19) United States
(12) Patent Application Publication
(10) Pub. No.: US 2026/0073102 A1
(43) Pub. Date: Mar. 12, 2026

(54) PETROPHYSICAL MODEL INTERPRETATION ASSISTANT SYSTEM

(71) Applicant: Schlumberger Technology Corporation, Sugar Land, TX (US)

(72) Inventors: Valerian Guillot, Montpellier (FR); Vanessa da Silva Simoes, Houston, TX (US); Kerry Huguet, Houston, TX (US); Jean-Etienne Jacolin, Montpellier (FR)

(21) Appl. No.: 18/883,839

(22) Filed: Sep. 12, 2024

(51) Int. Cl. G06F 30/28

(52) U.S. Cl. CPC G06F 30/28

(57) ABSTRACT

A system may include processing circuitry and memory storing instructions, where the instructions, when executed by the processing circuitry, cause the processing circuitry to receive a first set of measurements associated with a first set of wells and generate a first well model representative of a property associated with the first set of wells. The processing circuitry may generate a well property model representative of an expected property relative to a measurement associated with a well, receive a second set of measurements associated with a second set of wells, and generate a second well model representative of a first set of predicted measurements. The processing circuitry may generate an adjusted second well model based on the well property model and the second well model, determine a second set of predicted measurements, and instruct a display to display the first set of predicted measurements and the second set of predicted measurements.

### BACKGROUND

The present disclosure generally relates to monitoring various properties at a hydrocarbon well site. More specifically, the present disclosure relates to providing an interpretation system for determining the various properties at the hydrocarbon well site based on measurements from the hydrocarbon well site and one or more models.

During production, information related to the hydrocarbons extracted from a hydrocarbon well and/or related to equipment used to transport, store, or process the extracted hydrocarbons may be gathered at the well (e.g., the well site) or at various locations along the network of pipelines. Indeed, different wells may be equipped with different types of sensors that may provide varying degrees of insight into the operations of the wells. It may be beneficial to obtain more accurate predictions for various well properties by interpreting models of various wells.

### SUMMARY

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

In an embodiment, a system may include processing circuitry and memory storing instructions, where the instructions, when executed by the processing circuitry, cause the processing circuitry to receive a first set of measurements associated with a first set of wells, where the first set of wells is equipped with a first set of measurement tools, and generate a first well model representative of one or more properties associated with the first set of wells, where the first well model is generated based on the first set of measurements. The processing circuitry may also generate a well property model representative of one or more expected properties relative to one or more measurements associated with a well, where the well property model is generated based on the first well model and a pre-trained model related to the one or more expected properties, receive a second set of measurements associated with a second set of wells, where the second set of wells is equipped with a second set of measurement tools, and generate a second well model representative of a first set of predicted measurements associated with the second set of wells based on the second set of measurements. The processing circuitry may generate an adjusted second well model based on the well property model and the second well model, determine a second set of predicted measurements associated with the second set of wells based on the adjusted second well model, and instruct a display to display the first set of predicted measurements and the second set of predicted measurements.

The system of the preceding clause, wherein the first set of measurement tools comprises more equipment than the second set of measurement tools.

The system of any preceding clause, wherein the first set of measurement tools comprises more data points as compared to the second set of measurement tools. The system of any preceding clause, wherein the pre-trained model is generated based on a machine learning model and a plurality of datasets associated with a plurality of wells, and wherein the machine learning model is configured to identify one or more patterns in the plurality of datasets.

The system of any preceding clause, wherein the instructions, when executed by the processing circuitry, cause the processing circuitry to modify one or more well operations associated with the second set of wells based on the first set of predicted measurements, the second set of predicted measurements, or both.

The system of any preceding clause, wherein the instructions, when executed by the processing circuitry, cause the processing circuitry to receive an indication of adjusting at least one parameter associated determining the first set of predicted measurements, determine an adjusted first set of predicted measurements based on the indication and the second well model, and instruct the display to display the adjusted first set of predicted measurements, the second set of predicted measurements, or both

The system of the preceding clause, wherein the instructions, when executed by the processing circuitry, cause the processing circuitry to store the adjusted first set of predicted measurements in a storage component and update the pre-trained model based on the adjusted first set of predicted measurements.

In an embodiment, a method may include, via processing circuitry, receiving a first set of measurements associated with a first set of wells, where the first set of wells is equipped with a first set of measurement tools and generating a first well model representative of one or more properties associated with the first set of wells, where the first well model is generated based on the first set of measurements. The method may also, via the processing circuitry, generate a well property model representative of one or more expected properties relative to one or more measurements associated with a well, where the well property model is generated based on the first well model and a pre-trained model related to the one or more expected properties, receive a second set of measurements associated with a second set of wells, where the second set of wells is equipped with a second set of measurement tools, and generate a second well model representative of a first set of predicted measurements associated with the second set of wells based on the second set of measurements. The method may, via the processing circuitry, generate an adjusted second well model based on the well property model and the second well model, determine a second set of predicted measurements associated with the second set of wells based on the adjusted second well model, and instruct a display to display the first set of predicted measurements and the second set of predicted measurements.

The method of the preceding clause, including modifying, via the processing circuitry, one or more well operations associated with the second set of wells based on the first set of predicted measurements, the second set of predicted measurements, or both.

The method of any preceding clause, including training, via the processing circuitry, the pre-trained model using historical data associated with the first set of wells, the second set of wells, or both.

The method of the preceding clause, wherein the pre-trained model is configured to is configured to identify one or more patterns in the historical data.

The method of any preceding clause, including receiving, via the processing circuitry, an indication of adjusting at least one parameter associated determining the first set of predicted measurements, determining, via the processing circuitry, an adjusted first set of predicted measurements based on the indication and the second well model, and instructing, via the processing circuitry, the display to display the adjusted first set of predicted measurements, the second set of predicted measurements, or both.

The method of any preceding clause, wherein the first set of measurement tools comprises more data points as compared to the second set of measurement tools.

In an embodiment, a non-transitory, computer-readable medium comprising instructions that, when executed by a processor, causes the processor to perform operations including receive a first set of measurements associated with a first set of wells, where the first set of wells is equipped with a first set of measurement tools and generate a first well model representative of one or more properties associated with the first set of wells, where the first well model is generated based on the first set of measurements. The processor may also perform operations including generate a well property model representative of one or more expected properties relative to one or more measurements associated with a well, where the well property model is generated based on the first well model and a pre-trained model related to the one or more expected properties, receive a second set of measurements associated with a second set of wells, where the second set of wells is equipped with a second set of measurement tools, and generate a second well model representative of a first set of predicted measurements associated with the second set of wells based on the second set of measurements. The processor may perform operations including generate an adjusted second well model based on the well property model and the second well model, determine a second set of predicted measurements associated with the second set of wells based on the adjusted second well model, instruct a display to display the first set of predicted measurements and the second set of predicted measurements.

The tangible, non-transitory, computer-readable medium of the preceding clause, wherein the first set of measurement tools comprises more equipment than the second set of measurement tools.

The tangible, non-transitory, computer-readable medium of any preceding clause, wherein the pre-trained model is generated based on a machine learning model and a plurality of datasets associated with a plurality of wells, and wherein the machine learning model is configured to identify one or more patterns in the plurality of datasets.

The tangible, non-transitory, computer-readable medium of any preceding clause, wherein the instructions are configured to cause the processing circuitry to modify one or more well operations associated with the second set of wells based on the first set of predicted measurements, the second set of predicted measurements, or both.

The tangible, non-transitory, computer-readable medium of the preceding clause, wherein the first set of measurement tools comprises more data points as compared to the second set of measurement tools.

The tangible, non-transitory, computer-readable medium of any preceding clause, wherein the instructions are configured to cause the processing circuitry to receive an indication of adjusting at least one parameter associated determining the first set of predicted measurements, determine an adjusted first set of predicted measurements based on the indication and the second well model, and instruct the display to display the adjusted first set of predicted measurements, the second set of predicted measurements, or both.

The tangible, non-transitory, computer-readable medium of the preceding clause, wherein the instructions are configured to cause the processing circuitry to store the adjusted first set of predicted measurements in a storage component and update the pre-trained model based on the adjusted first set of predicted measurement.

### BRIEF DESCRIPTION OF THE DRAWINGS

These and other features, aspects, and advantages of the present disclosure will become better understood when the following detailed description is read with reference to the accompanying drawings in which like characters represent like parts throughout the drawings, wherein:

FIG. 1 illustrates a schematic diagram of an example hydrocarbon site that may produce and process hydrocarbons, in accordance with embodiments of the present disclosure;

FIG. 2 illustrates a block diagram of an interpretation system that may be employed in and/or receive measurements from the hydrocarbon site of FIG. 1, in accordance with embodiments of the present disclosure;

FIG. 3 illustrates a data flow diagram for generating predicted measurements using Tier 2 well measurements by the interpretation system of FIG. 2, in accordance with embodiments of the present disclosure;

FIG. 4 illustrates a graphical user interface (GUI) presenting generated outputs of the interpretation system of FIG. 2, in accordance with embodiments of the present disclosure; and

FIG. 5 illustrates a flow diagram of an example method for interpreting measurements from a well of the hydrocarbon site of FIG. 1, in accordance with embodiments of the present disclosure.

### DETAILED DESCRIPTION

Certain embodiments commensurate in scope with the present disclosure are summarized below. These embodiments are not intended to limit the scope of the disclosure, but rather these embodiments are intended only to provide a brief summary of certain disclosed embodiments. Indeed, the present disclosure may encompass a variety of forms that may be similar to or different from the embodiments set forth below.

As used herein, the term “coupled” or “coupled to” may indicate establishing either a direct or indirect connection (e.g., where the connection may not include or include intermediate or intervening components between those coupled), and is not limited to either unless expressly referenced as such. The term “set” may refer to one or more items. Wherever possible, like or identical reference numerals are used in the figures to identify common or the same elements. The figures are not necessarily to scale and certain features and certain views of the figures may be shown exaggerated in scale for purposes of clarification.

As used herein, the terms “inner” and “outer”; “up” and “down”; “upper” and “lower”; “upward” and “downward”; “above” and “below”; “inward” and “outward”; and other like terms as used herein refer to relative positions to one another and are not intended to denote a particular direction or spatial orientation. The terms “couple,” “coupled,” “connect,” “connection,” “connected,” “in connection with,” and “connecting” refer to “in direct connection with” or “in connection with via one or more intermediate elements or members.”

Furthermore, when introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment,” “an embodiment,” or “some embodiments” of the present disclosure are not intended to be interpreted as excluding the existence of additional embodiments that also incorporate the recited features. Furthermore, the phrase A “based on” B is intended to mean that A is at least partially based on B. Moreover, unless expressly stated otherwise, the term “or” is intended to be inclusive (e.g., logical OR) and not exclusive (e.g., logical XOR). In other words, the phrase A “or” B is intended to mean A, B, or both A and B.

Hydrocarbon well sites (e.g., hydrocarbon wells, wells) may include a number of components that facilitates the extraction, processing, and distribution of hydrocarbons (e.g., oil) from a well or well site. In various hydrocarbon well sites, different types of equipment and/or number of devices may be used to acquire information regarding certain wells. The wells may be categorized into different groups based on the amount of equipment and/or the type of equipment disposed within the well. For example, Tier 1 wells (e.g., high tier wells, first set of wells) may include more sophisticated equipment (e.g., increased number of sensors, different types of sensors) in comparison to Tier 2 wells (e.g., low tier wells, second set of wells). Additionally or alternatively, the Tier 1 wells may include more equipment (e.g., computing systems, fracturing systems) in comparison to the Tier 2 wells. As such, the Tier 1 wells may be associated with more measurements and/or more useful measurements (e.g., data rich) for interpreting the Tier 1 well measurements (e.g., a first set of measurements) in comparison to measurements from the Tier 2 wells. Indeed, it may be difficult to perform a quantitative interpretation using the Tier 2 well measurements (e.g., a second set of measurements) due to lack of available measurements, lack of certain types of measurements, lack of quality measurements, and the like. As such, obtaining various properties related to the Tier 2 wells based on the Tier 2 well measurements may be difficult as compared to obtaining various properties of Tier 1 wells using the Tier 1 well measurements.

With this in mind, Tier 1 wells may be monitored by more sophisticated equipment and/or a greater number of equipment in comparison to Tier 2 wells. As such, Tier 1 well measurements may be readily used to determine various properties (e.g., porosity, permeability, saturation). For example, Tier 1 well measurements may include compressional slowness, shear slowness, composition (e.g., mineral composition, elemental composition, rock type), core measurements, dielectric properties, and so on, while Tier 2 well measurements may include gamma ray, bulk density, resistivity, and so on. The Tier 1 well measurements may be readily used for interpretation (e.g., quantitative interpretation) using models (e.g., physics-based models, well models) to determine production changes, identify reservoir locations, improve efficiencies in production operations, and the like. That is, interpreting the Tier 1 well measurements may identify intervals of interest and/or areas of the hydrocarbon site and/or the Tier 1 well for perforation. In contrast, it may be difficult to perform quantitative interpretation using the Tier 2 well measurements due to lack of available measurements, lack of certain types of measurements, lack of quality measurements, and the like. For example, the Tier 2 well measurements may include data with noise, missing data, and the like. As such, obtaining various properties related to the wells based on an interpretation of the Tier 2 well measurements may be difficult as compared to the interpretation of the wells using the Tier 1 well measurements.

With the foregoing in mind, embodiments of the present disclosure are generally directed to an interpretation system that may receive measurements from a Tier 2 well and output an interpretation for the Tier 2 well based on the Tier 2 measurements, an interpretation system, and/or models associated with the wells. The interpretation system may use measurements from Tier 1 wells in a particular area to generate a model (e.g., physics-based model) representative of various properties (e.g., porosity) of the well, the subsurface region of the well, and the like. For example, the interpretation system may receive the Tier 1 well measurements and generate an interpretation of the Tier 1 well based on the Tier 1 well measurements to determine certain properties that may be present in the well. The interpretation system may determine the properties based on the collective data provided in the Tier 1 well measurements.

The interpretation system may apply pre-trained well models to the interpreted properties and the Tier 1 well measurements to generate a well model representative of the expected properties of the Tier 1 well relative to various data variables. That is, the interpretation system may use machine learning algorithms to predict the behavior of the Tier 2 well using the collected Tier 1 well measurements and the pre-trained well models that may correspond to similar wells, well measurements, and the like. In some embodiments, the pre-trained well models may account for relationships between Tier 1 well measurements and Tier 2 well measurements with respect to the properties of the well. Indeed, the pre-trained well models may include a machine learning model that may be trained with datasets that include variations in measurements to capture the properties of the well as various input datasets change. In other words, the pre-trained well model may be trained using historical measurements (e.g., data) from other Tier 1 wells and/or Tier 2 wells. As a result, the interpretation system may generate a well property model that may predict a particular property of the well based on input measurements. For example, the porosity of a Tier 2 well may be predicted based on the Tier 2 well measurements using the well property model.

Keeping this in mind, the interpretation system may receive the well property model and Tier 2 well measurements from equipment positioned within the Tier 2 wells. In some embodiments, the Tier 2 well measurements may be used to generate a Tier 2 model representative of properties of the Tier 2 wells. However, since the Tier 2 well model is generated using just the Tier 2 well measurements, the resulting model may not be as accurate as compared to the model being generated with the Tier 1 well measurements. As such, the interpretation system may retrieve the well property model and apply it to the Tier 2 well model and the Tier 2 well measurements to generate enhanced property data for the second set of wells. In this way, wells having fewer devices or less sophisticated equipment may still be interpreted with a higher degree of accuracy while efficiently employing equipment, acquiring additional datasets, and the like.

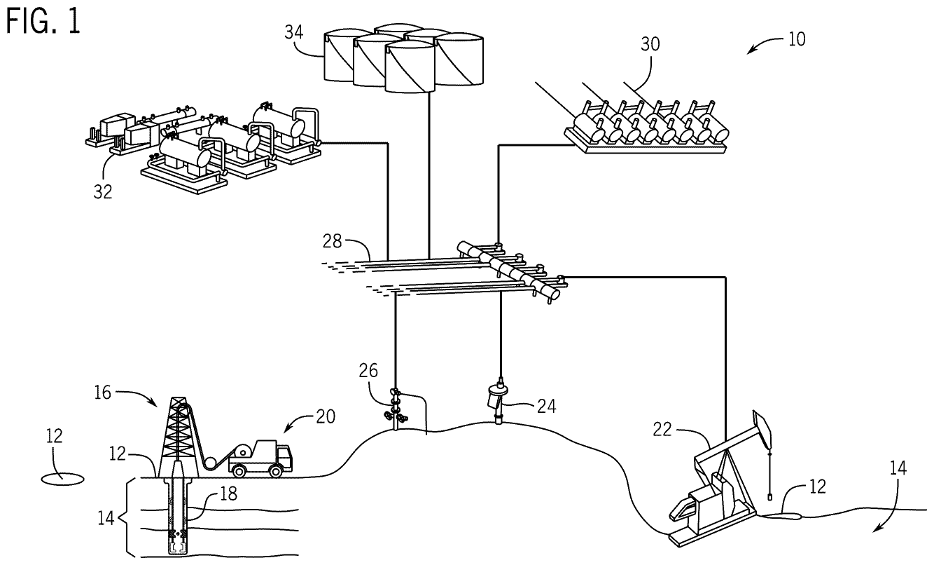

Accordingly, the present embodiments described herein are related to systems and methods for an interpretation system that receives measurements associated with Tier 2 wells and interprets the measurements to generated predicted measurements with higher accuracy as compared to the original measurements. That is, the present embodiments described herein are related to an interpretation system that outputs an interpretation for the Tier 2 well based on Tier 2 well measurements, an inference system, and/or models associated with the well. Additional details with regard to the interpretation system interpreting measurements associated with a Tier 2 well and/or outputting properties associated with the Tier 2 well with reference to FIGS. 1-5.

By way of introduction, FIG. 1 illustrates a schematic diagram of an example hydrocarbon site 10 where hydrocarbon products, such as crude oil and natural gas, may be extracted from the ground, processed, and stored. Datasets related to the operation of the hydrocarbon site 10 may be employed in accordance with the present embodiments. As shown in FIG. 1, the hydrocarbon site 10 may include a number of components or facilities that correspond to wells, processing facilities, collection components, distribution networks, and the like. During the design phase of planning for the types of components to use at the hydrocarbon site 10, the locations of the components at the hydrocarbon site 10, and other design properties, a variety of factors are taken under consideration.

The hydrocarbon site 10 may include a number of wells 12 disposed within a geological formation. As used herein, wells 12 may generally refer to physical components such as the drilling platform 16 and wellbore 18 and/or the general area of the reservoir in which extraction is desired (e.g., a reservoir well section). In certain instances, the wells 12 may be grouped into two categories based on the components positioned within and/or around the wells 12. For example, the wells 12 may include Tier 1 wells (e.g., high tier wells, a first set of wells), which may be associated with a first set of measurements (e.g., datasets), and Tier 2 wells (e.g., low tier wells, a second set of wells), which may be associated with a second set of measurements. In another example, the components positioned within and/or around the Tier 1 wells may be more sophisticated and/or generate more measurements in comparison to the components positioned within the Tier 2 wells. The components positioned within and/or around the Tier 1 wells may include a litho scanner, nuclear magnetic resonance (NMR) spectroscopy, wireline sonics, and the like, while the components positioned within and/or around the Tier 2 wells may include spectral devices, logging tools, and the like. As will be appreciated herein, the components positioned within and/or around the Tier 1 wells may generate a first set of measurements and the components positioned within and/or around the Tier 2 wells may generate a second set of measurements. Furthermore, the Tier 1 wells may account for up to 10% of wells 12 within the hydrocarbon site 10 and the Tier 2 wells may account for the remaining wells 12 within the hydrocarbon site 10.

The drilling operations may include drilling the wellbore 18, injecting drilling fluids into the wellbore 18, performing casing operations within the wellbore 18, and the like. For example, the present embodiments are directed to an interpretation system that identifies certain areas of the wellbore 18 for perforation based on the first set of measurements and/or the second set of measurements to improve the drilling and/or production operations. In addition to including the drilling platform 16, the hydrocarbon site 10 may include surface equipment 20 that may carry out certain operations, such as cement installation operation, well logging operations to detect conditions of the wellbore 18, and the like. As such, the surface equipment 20 may include equipment that store cement slurries, drilling fluids, displacement fluids, spacer fluids, chemical wash fluids, and the like. The surface equipment 20 may include piping and other materials used to transport the various fluids described above into the wellbore 18. The surface equipment 20 may also include pumps and other equipment (e.g., batch mixers, centrifugal pumps, liquid additive metering systems, tanks, etc.) that may fill in the interior of a casing string with the fluids discussed above.

In addition to the equipment used for drilling operations, the hydrocarbon site may include a number of well devices that may control the flow of hydrocarbons being extracted from the wells 12. For instance, the well devices in the hydrocarbon site 10 may include pumpjacks 22, submersible pumps 24, well trees 26, and the like. The pumpjacks 22 may mechanically lift hydrocarbons (e.g., oil) out of the well 12 when a bottom hole pressure of the well 12 is not sufficient to extract the hydrocarbons to the surface. The submersible pump 24 may be an assembly that may be submerged in a hydrocarbon liquid that may be pumped. As such, the submersible pump 24 may include a hermetically sealed motor, such that liquids may not penetrate the seal into the motor. Further, the hermetically sealed motor may push hydrocarbons from underground areas or the reservoir to the surface. The well trees 26 may be an assembly of valves, spools, and fittings used for natural flowing wells. As such, the well trees 26 may be used for an oil well, gas well, water injection well, water disposal well, gas injection well, condensate well, and the like. By way of reference, the wells 12 may be part of a first hierarchical level and the well devices that extract hydrocarbons from the wells 12 may be part of a second hierarchical level above the first hierarchical level. Each hierarchical level may include a number of components and the presently disclosed techniques may account for these levels when determining the design plans for the hydrocarbon site 10.

After the hydrocarbons are extracted from the surface via the well devices, the extracted hydrocarbons may be distributed to other devices via a network of pipelines 28. That is, the well devices of the hydrocarbon site 10 may be connected together via a network of pipelines 28. In addition to the well devices described above, the network of pipelines 28 may be connected to other collecting or gathering components, such as wellhead distribution manifolds 30, separators 32, storage tanks 34, and the like.

In some embodiments, the pumpjacks 22, the submersible pumps 24, well trees 26, wellhead distribution manifolds 30, separators 32, and storage tanks 34 may be connected together via the network of pipelines 28. The wellhead distribution manifolds 30 may collect the hydrocarbons that may have been extracted by the pumpjacks 22, the submersible pumps 24, and the well trees 26, such that the collected hydrocarbons may be routed to various hydrocarbon processing or storage areas in the hydrocarbon site 10. The separator 32 may include a pressure vessel that may separate well fluids produced from oil and gas wells into separate gas and liquid components. For example, the separator 32 may separate hydrocarbons extracted by the pumpjacks 22, the submersible pumps 24, or the well trees 26 into oil components, gas components, and water components. After the hydrocarbons have been separated, each separated component may be stored in a particular storage tank 34. The hydrocarbons stored in the storage tanks 34 may be transported via the pipelines 28 to transport vehicles, refineries, and the like.

Although the hydrocarbon site 10 is described above with certain components, it should be understood that the hydrocarbon site 10 may include additional, fewer, or different components. For example, although discussed above in relation to a hydrocarbon site 10 on land, present embodiments may also include analysis of off-shore hydrocarbon sites 10 and the components thereof. That is, the embodiments described herein are directed to identifying intervals of interest for any suitable hydrocarbon site that may include various types of components that is related to the production and distribution of hydrocarbons. In this way, the components depicted in FIG. 1 are provided as an example context in which the embodiments described herein may be implemented. As such, the embodiments of this disclosure should not be limited to the components listed in FIG. 1.

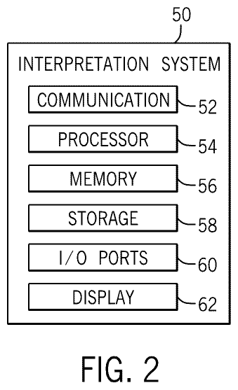

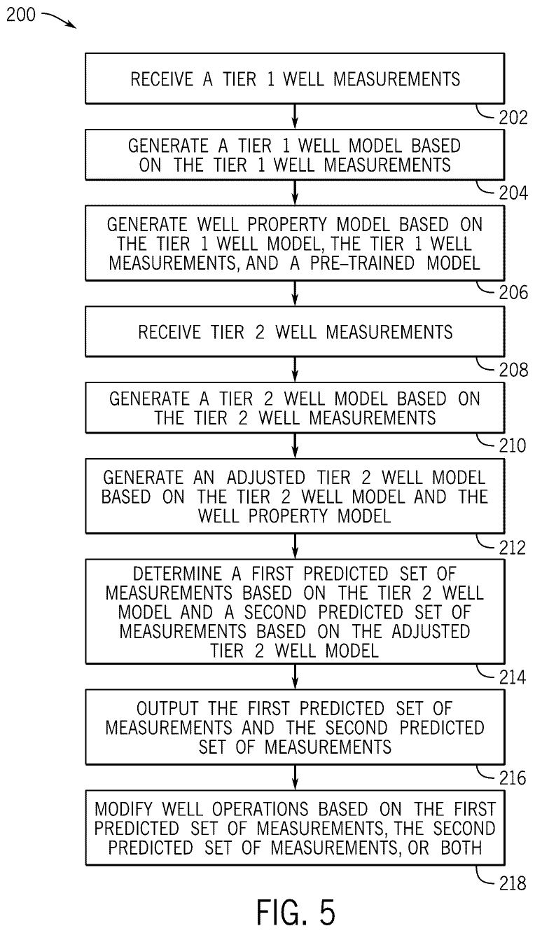

Keeping this in mind, the present embodiments described herein may include systems and methods for identifying intervals of interest within the wellbore 18 for drilling and/or production operations. For example, an interpretation system 50, as presented in FIG. 2, may receive the second set of measurements from the Tier 2 wells and determine a predicted set of measurements of a property of the Tier 2 wells according to a process that will be described in greater detail below with respect to FIG. 5.

Referring now to FIG. 2, the interpretation system 50 may include any suitable computing device, cloud-computing device, or the like and may include various components to perform various analysis operations. As shown in FIG. 2, the interpretation system 50 may include a communication component 52, a processor 54, a memory 56, a storage component 58, input/output (I/O) ports 60, a display 62, and the like. The communication component 52 may be a wireless or wired communication component that may facilitate communication between different monitoring systems, gateway communication devices, various control systems, and the like. The processor 54 may be any type of computer processor or microprocessor capable of executing computer-executable code. The memory 56 and the storage component 58 may be any suitable articles of manufacture that can serve as media to store processor-executable code, data, or the like. These articles of manufacture may represent non-transitory computer-readable media (i.e., any suitable form of memory or storage) that may store the processor-executable code used by the processor 54 to perform the presently disclosed techniques. The memory 56 and the storage component 58 may also be used to store data received via the I/O ports 60, data analyzed by the processor 54, or the like.

The I/O ports 60 may be interfaces that couple to various types of I/O modules such as sensors, programmable logic controllers (PLC), and other types of equipment. For example, the I/O ports 60 may serve as an interface to pressure sensors, flow sensors, temperature sensors, and the like. As such, the interpretation system 50 may receive data associated with a well via the I/O ports 60. The I/O ports 60 may also serve as an interface to enable the interpretation system 50 to connect and communicate with surface instrumentation, servers, and the like.

The display 62 may include any type of electronic display such as a liquid crystal display, a light-emitting-diode display, and the like. As such, data acquired via the I/O ports and/or data analyzed by the processor 54 may be presented on the display 62, such that the interpretation system 50 may present production datasets related to operations of the hydrocarbon site 10 for view. In certain embodiments, the display 62 may be a touch screen display or any other type of display capable of receiving inputs from an operator. Although the interpretation system 50 is described as including the components presented in FIG. 2, the interpretation system 50 should not be limited to including the components listed in FIG. 2. Indeed, the interpretation system 50 may include additional or fewer components than described above.

With the foregoing in mind, the interpretation system 50 may interpret the second set of measurements from a Tier 2 well to improve drilling and/or production operations based on models generated using Tier 1 well measurements. As discussed herein, hydrocarbon sites 10 may include wells categorized into different groups based on the amount of equipment and/or the type of equipment disposed within the well. For example, Tier 1 wells (e.g., high tier wells, first set of wells) may include more sophisticated equipment (e.g., increased number of sensors, different types of sensors) in comparison to Tier 2 wells (e.g., low tier wells, second set of wells). Additionally or alternatively, the Tier 1 wells may include more equipment (e.g., computing systems, fracturing systems) in comparison to the Tier 2 wells. As such, the Tier 1 wells may be associated with more measurements and/or more useful measurements (e.g., data rich) for interpreting the Tier 1 well measurements (e.g., a first set of measurements) in comparison to measurements from the Tier 2 wells.

By way of example, the interpretation system 50 may generate a Tier 2 well model based on the Tier 2 well measurements associated with a Tier 2 well and interpret the Tier 2 well model to determine properties of the Tier 2 well. Additionally, the interpretation system 50 may employ a well property model to predict certain properties (e.g., porosity, permeability, saturation) of the Tier 2 wells based on a Tier 1 well model (e.g., a first well model), which may be generated based on Tier 1 well measurements, and a pre-trained model, which may provide expected and/or predicted measurements for various properties of the well based on various models (e.g., deep learning model). In some embodiments, the interpretation system 50 may generate an adjusted Tier 2 well model (e.g., an adjusted second well model) using the well property model and the Tier 2 well model (e.g., a second well model). Then, the interpretation system 50 may interpret the adjusted Tier 2 well model to determine expected or predicted values (e.g., predicted set of measurements) for a particular property of the Tier 2 well. The interpretation system 50 may output both a first set of predicted measurements for a property of the Tier 2 well that may be determined based on the Tier 2 well model and a second set of predicted measurements for the property that may be determined based on the adjusted Tier 2 well model. As such, a user may view differences between the generated sets of predicted measurements for the property to better assess the differences between employing the different well models.

In some embodiments, the user may adjust the certain parameters of a well model used to generate the first or second set of predicted measurements. For example, the interpretation system 50 may determine the set of predicted measurements of the Tier 2 well based on one or more parameters associated with the respective model. For example, the parameters associated with porosity may include various bulk density values, fluid salinity values, gamma ray values. In some embodiments, the interpretation system 50 may present a panel visualization with the parameters used to determine the set of predicted measurements of the Tier 2 well. The user may adjust a value of the parameters via a graphical user interface, thereby adjusting the set of predicted measurements. In other words, the interpretation system 50 may adjust parameters of the Tier 2 well model determine an adjusted set of predicted measurements of the Tier 2 well. In some embodiments, the interpretation system 50 may receive an indication of approval of the set of predicted measurements and parameters and store the respective set of predicted measurements. As such, the interpretation system 50 may interpret measurements from wells having fewer components and/or less sophisticated components with a higher degree of accuracy.

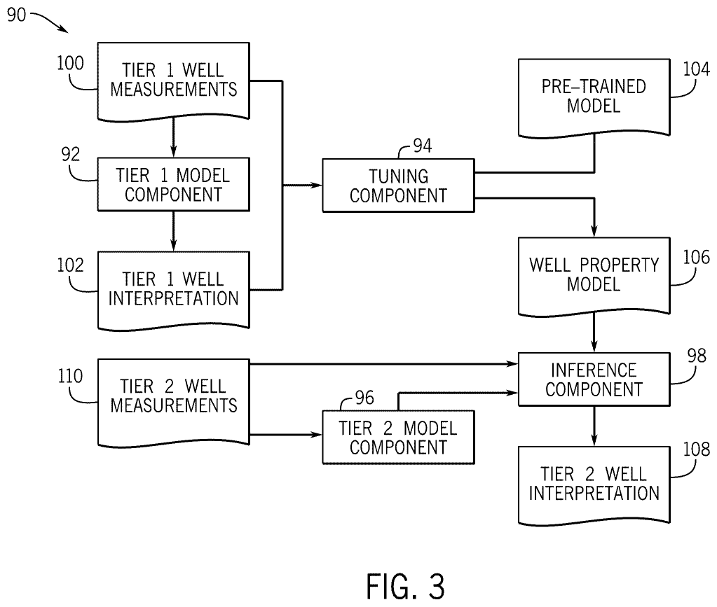

FIG. 3 illustrates a data flow diagram 90 for generating predicted measurements using Tier 2 well measurements in accordance with embodiments described herein as performed by the interpretation system 50. As discussed herein, the interpretation system 50 may generate an interpretation (e.g., set of predicted measurements) of a Tier 2 well to improve drilling and/or production operations within the hydrocarbon site 10. To this end, the interpretation system 50 may include a Tier 1 model component 92, a tuning component 94, a Tier 2 model component 96, and an inference component 98. Although the Tier 1 model component 92, the tuning component 94, the Tier 2 model component 96, and the inference component 98 are illustrated as separate components in FIG. 3, it may be understood that the components may be implemented by one component (e.g., one processor), one processing device, and/or a cloud-based server. In other embodiments, the components of the interpretation system 50 may be implemented on different processing devices and/or by different processors.

The interpretation system 50 may receive Tier 1 well measurements 100 from Tier 1 wells (e.g., high tier wells, first set of wells) within the hydrocarbon site 10. The Tier 1 well measurements 100 may be associated with wells within a certain area of the hydrocarbon site 10, within a certain radius within the hydrocarbon site 10, and/or generally positioned with the hydrocarbon site 10. For example, the Tier 1 well measurements 100 may be generated by components positioned within the Tier 1 well. The Tier 1 well measurements 100 may include compressional slowness, shear slowness, composition (e.g., mineral composition, elemental composition, rock type), core measurements, dielectric properties, and so on, while Tier 2 well measurements may include gamma ray, bulk density, resistivity, and so on.

The interpretation system 50 may use the Tier 1 well measurements 100 to generate a model (e.g., physics-based model) representative of various properties of the well, the subsurface region of the well, and the like. The property may include a permeability of the well, a saturation of the well, a porosity of the well, and so on. In particular, the Tier 1 model component 92 may use the Tier 1 well measurements 100 to generate a Tier 1 well interpretation 102 based on the Tier 1 well measurements 100. The Tier 1 well interpretation 102 may include a Tier 1 well model representative of certain properties that present in the well. The Tier 1 well model may include a set of expected measurements or values for various properties of the respective well determined based on a set of Tier 1 well measurements 100. As such, the interpretation system 50 may generate the Tier 1 well model using collective data provided in the Tier 1 measurements 100. Additionally or alternatively, the Tier 1 model component 92 may determine a set of predicted measurements associated with one or more properties of the Tier 1 well based on the Tier 1 well model and/or the Tier 1 well measurements as part of the Tier 1 well interpretation 102. In some cases, the Tier 1 model component 92 may be associated with certain model parameters that may adjust the outputs of the Tier 1 well model to tune or calibrate the generated set of predicted measurements of the property. In some embodiments, the Tier 1 model component 92 may retrieve the parameters from the memory 56, a cloud storage component, the storage component 58, and the like. As discussed herein, the Tier 1 well measurements 100 may be complete and/or high quality measurements in comparison to measurements from Tier 2 wells. As such, the Tier 1 well model and/or the property of the Tier 1 well may be determined with higher accuracy as compared to Tier 2 wells.

In an embodiment, the interpretation system 50 may generate and store the Tier 1 well interpretation 102. For example, the Tier 1 model component 92 may generate the Tier 1 well interpretation 102 and store the Tier 1 well interpretation 102 in the memory, the storage component, a database, and the like. After a period of time, the interpretation system 50 may retrieve the Tier 1 well interpretation 102, such as when the interpretation system 50 may be interpreting Tier 2 well measurements 110. As discussed herein, it may be difficult to perform a quantitative interpretation of the Tier 2 well measurements 110 due to lack of available measurements, lack of certain types of measurements, an the like. For example, the Tier 2 well measurements 110 may include noisy data, may be missing certain portions of data, may be missing certain types of data, and so on. As such, the interpretation system 50 may use a pre-trained model 104 and/or a well property model 106 to improve interpretation of Tier 2 well measurements 110. The pre-trained model 104 may provide expected or predicted measurements for various properties of a well based on a collection of datasets from various wells and one or more machine learning algorithms used to glean the patterns of well properties relative to various input datasets. Additional details regarding the pre-trained model 104 will be described below.

With the forgoing in mind, the interpretation system 50 may apply the pre-trained models 104 to the Tier 1 well interpretation 102 and/or the Tier 1 well measurements 100 to generate a well property model 106 representative of the expected properties of the Tier 2 well relative to various data variables. For example, the tuning component 94 may retrieve one or more pre-trained models 104 from the storage component 58. The pre-trained models 104 may include deep learning models, machine learning algorithms, artificial intelligence techniques, large language models, neural network algorithms, and so on. By way of example, the pre-trained models 104 may include a machine learning model trained with datasets (e.g., measurements) that include variations in measurements to capture the properties of the well as various input datasets change. The datasets may be associated with Tier 1 wells, Tier 2 wells, or both. In other words, the pre-trained models 104 may be trained using historical measurements (e.g., data) from other Tier 1 wells and/or Tier 2 wells. The tuning component 94 use the pre-trained models 104 to predict the properties of the Tier 2 well using the collected Tier 1 measurements 100 and the pre-trained models 104 that may correspond to similar wells, well measurements, and the like. In some embodiments, the pre-trained models 104 may account for relationships between Tier 1 well measurements 100 and Tier 2 well measurements 110 with respect to the properties of the well. As a result, the tuning component 94 may generate a well property model 106 that may predict a particular property of a well based on input measurements. For example, the tuning component 94 may predict porosity of a Tier 2 well using the well property model 106 and the Tier 2 well measurements 110.

In an embodiment, the interpretation system 50 may generate and store the well property model 106. The well property model 106 may predict one or more properties based on Tier 2 well measurements 110. For example, the tuning component 94 may generate the well property model 106 and store the well property model 106 in the storage component 58, a database, and the like. After a period of time, the interpretation system 50 may retrieve the well property model 106 for an interpretation, such as when the interpretation system 50 may be interpreting Tier 2 well measurements 110.

The interpretation system 50 may generate a Tier 2 well interpretation 108 based on the Tier 2 well measurements 110. The Tier 2 well interpretation 108 may include a Tier 2 well model associated with the Tier 2 well measurements 110, and as further described herein, the Tier 2 well interpretation 108 may include an adjusted Tier 2 well model. The interpretation system 50 may receive the Tier 2 well measurements 110 from the components disposed within and/or proximate to a Tier 2 well. As discussed herein, the Tier 2 well measurements 110 may be a lower quality/quantity in comparison to the Tier 1 well measurements 100. For example, the Tier 2 well measurements 110 may include more noise, fewer measurements (e.g., data points), and/or fewer useful measurements in comparison to the Tier 1 well measurements 100. As such, it may be more difficult to interpret the Tier 2 well measurements 110 in comparison to the Tier 1 well measurements 100. With the foregoing in mind, the Tier 2 model component 96 may generate the Tier 2 well interpretation 108 based on the Tier 2 well measurements 110. For example, the Tier 2 model component 96 may generate a Tier 2 well model based on the Tier 2 well measurements 110. In another example, the Tier 2 model component 96 may analyze the Tier 2 well model to determine one or more parameters that may be applied to the Tier 2 well model to generate a set of measurements associated with property of the Tier 2 well.

The interpretation system 50 may also generate an adjusted (e.g., tuned) Tier 2model based on the well property model 106, the Tier 2 well model, Tier 2 well measurements 110. For example, the inference component 98 may receive the Tier 2 well measurements 110, the Tier 2 well model from the Tier 2 model component 96, and retrieve the well property model 106 to generate an adjusted Tier 2 well model (e.g., the Tier 2 well interpretation 108) representative of predicted set of measurements of the Tier 2 well. The inference component 98 may include a model specialized to a particular set of parameters. For example, the inference component 98 may be generated based on stored measurements from Tier 1 wells, Tier 2 wells, or both and a parameter. The inference component 98 may adjust the Tier 2 well model based on a parameter. For example, the inference component 98 may adjust (e.g., tune) the Tier 2 well model based on the specialized set of parameters and the well property model 106 to generate an adjusted Tier 2 well model, which may be used to determine a predicted set of measurements of the Tier 2 well. The adjusted Tier 2 well model may be adjusted for a certain parameter. That is, the adjusted Tier 2 well model may include an enhanced set of property data associated with the Tier 2 wells. The inference component 98 may analyze the Tier 2 well model to determine one or more parameters that may be applied to the Tier 2 well model to generate (e.g., infer) a predicted set of measurements for the property of the Tier 2 well. In other words, the inference component 98 may generate a Tier 2 well interpretation 108 based on the Tier 2 well model, the Tier 2 well measurements 110, and the well property model 106. In this way, the interpretation system 50 may retrieve the well property model 106 and apply it to the Tier 2 model and the Tier 2 measurements 110 to generate enhanced predicted set of measurements for the Tier 2 well.

The interpretation system 50 may display a first predicted set of measurements of the Tier 2 well and a second predicted set of measurements of the Tier 2 well on a display (e.g., display 62). For example, the inference component 98 may receive a first predicted set of measurements (e.g., Tier 2 well interpretation 108) from the Tier 2 model component 96. The first predicted set of measurements may be determined by the Tier 2 model component 96 based on the Tier 2 well model and the Tier 2 well measurements. Additionally or alternatively, the inference component 98 may determine a second predicted set of measurements (e.g., Tier 2 well interpretation 108) based on the adjusted Tier 2 well model and the Tier 2 well measurements. The inference component 98 may output both the first predicted set of measurements and the second predicted set of measurements on the display 62) for display. The first predicted set of measurements and/or the second predicted set of measurements may be used to determine intervals of interest within the Tier 2 well and/or a position within the Tier 2 well for drilling and/or production operations. Additionally or alternatively, the interpretation system 50 may instruct one or more components positioned within and/or around the Tier 2 well to adjust operations based on the first predicted set of measurements and/or the second predicted set of measurements. In certain instances, the interpretation system 50 may instruct one or more components within the Tier 2 wells to perform or adjust an operation, such as perforating an area within the Tier 2 well. In other instances, the interpretation system 50 may provide an indication to one or more output devices to move positions within the hydrocarbon site to an interval of interest, an area for perforation, or both. As such, the interpretation system 50 may improve drilling and/or production operations within the hydrocarbon site (e.g., hydrocarbon site 10) by issuing commands to respective devices to adjust operations based on the analysis gleaned from the predicted set of measurements.

In certain embodiments, the Tier 2 model component 96 may generate both the Tier 2 well model and the adjusted Tier 2 well model as the Tier 2 interpretations 108. For example, the Tier 2 model component 96 may first generate the Tier 2 well model based on the Tier 2 well measurements 110. The Tier 2 model component 96 may receive and/or apply a model, a specialized set of parameters, or both from the inference component 98 to adjust the Tier 2 well model. Additionally or alternatively, the Tier 2 model component 96 may determine a first predicted set of measurements associated with the Tier 2 well based on the Tier 2 well model and a second predicted set of measurements associated with the Tier 2 well based on the adjusted Tier 2 well model. The interpretation system 50 may output both the first predicted set of measurements and the second predicted set of measurements for display. In this way, wells having fewer devices or less sophisticated equipment may still be interpreted with a higher degree of accuracy while efficiently employing equipment, acquiring additional datasets, and the like.

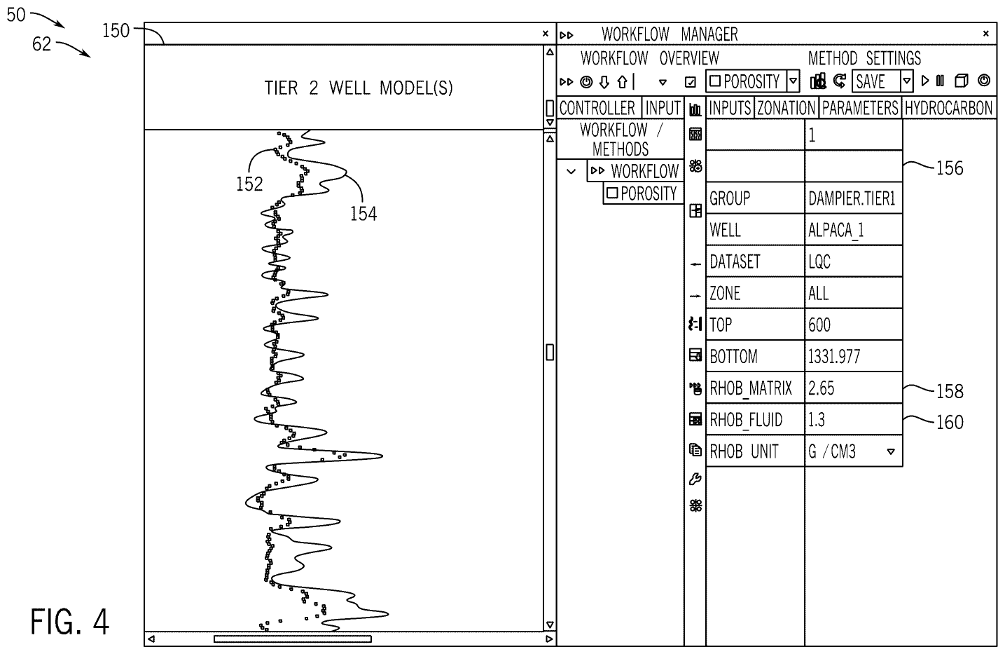

FIG. 4 illustrates a graphical user interface (GUI) 150 presenting generated outputs of the interpretation system 50. The GUI 150 may display a Tier 2 well interpretation (e.g., the Tier 2 well interpretation 108) generated by the interpretation system 50. The well interpretations may include a predicted set of measurements (e.g., a property) associated with a well. For example, the GUI 150 may display a first predicted set of measurements 152 associated with the Tier 2 well model and a second predicted set of measurements 154 associated with the adjusted Tier 2 well model. The GUI 150 may also display a panel 156 with one or more parameters 158, 160 that may adjust the first predicted set of measurements 152.

As illustrated on the GUI 150, the first predicted set of measurements 152 may be displayed using a solid black line and the second predicted set of measurements 154 may be displayed using a dotted line. By way of example, the first predicted set of measurements 152 and the second predicted set of measurements 154 may be associated with a porosity of the Tier 2 well. In other instances, the predicted set of measurements 152, 154 may also include permeability, saturation, and the like. As discussed herein, the Tier 2 well measurements 110 may lack certain measurements and/or certain types of measurements, which may introduce error into the first predicted set of measurements 152. The error may be indicated by a difference between the first predicted set of measurements 152 and the second predicted set of measurements 154.

The interpretation system 50 may adjust the first predicted set of measurements 152 based on any suitable number of parameters (e.g., first parameter 158, second parameter 160). By way of illustrative example and as illustrated in FIG. 4, a first parameter 158 may include RHOB_matrix and the second parameter 160 may include RHOB_fluid. The first parameter 158 and the second parameter 160 may be associated with bulk density and used by the interpretation system 50 to predict a porosity of the well 12 based on the Tier 2 well model. That is, the first parameter 158 and the second parameter 160 may be applied by the interpretation system 50 to the Tier 2 well model to generate the first predicted set of measurements 152. In certain instances, the interpretation system 50 may receive an adjustment to a value of the first parameter 158 and/or the second parameter 160 via the GUI 150. In response to receiving the adjustment, the interpretation system 50 may apply the adjusted parameter to the Tier 2 well model to adjust the first predicted set of measurements 152. The interpretation system 50 may populate the GUI 150 with the adjusted first predicted set of measurements 152 in real-time. In certain instances, the adjustment to the first parameter 158 and/or the second parameter 160 may reduce the difference between the first predicted set of measurements 152 and the second predicted set of measurements 154, thereby reducing the error of the first predicted set of measurements 152. As such, the interpretation system 50 may improve interpretation of wells having fewer components and/or less sophistical components with a higher degree of accuracy.

The interpretation system 50 may store the first predicted set of measurements 152, the second predicted set of measurements 154, the first parameter 158, and/or the second parameter 160 in the storage component 58. For example, the interpretation system 50 may receive an indication to associate the first predicted set of measurements 152, the first parameter 158, and/or the second parameter 160 with the Tier 2 wells and store the association. In another example, the interpretation system 50 may receive an indication to associate the second predicted set of measurements 154 with the Tier 2 wells and store the association. The interpretation system 50 may store the associations as historical data, which may be used to further train the pre-trained models 104. As such, the interpretation system 50 may continuously improve the association between Tier 1 well measurements 100 and Tier 2 well measurements 110, the interpretation of Tier 2 well measurements based on different models, and so on.

FIG. 5 illustrates a flow diagram of an example method 200 for interpreting measurements from a well of the hydrocarbon site. The method 200 will be described as being performed by the interpretation system 50, but it should be noted that any suitable processor-based device may be specially programmed to perform any of the steps of the method described herein. It should be understood that the method 200 described below may include some or all the steps illustrated in FIG. 5. Furthermore, it should be understood that the steps of the method 200 may not be performed in the specific order shown illustrated.

At block 202, the interpretation system 50 may receive Tier 1 well measurements. For example, the interpretation system 50 (e.g., Tier 1 model component 92) may receive Tier 1 well measurements 100 from components (e.g., equipment) positioned within and/or proximate to one or more Tier 1 wells in the hydrocarbon site 10. In another example, the interpretation system 50 may retrieve the Tier 1 well measurements 110 from the storage component 58.

At block 204, the interpretation system 50 may generate a Tier 1 well model based on the Tier 1 well measurements. For example, the interpretation system 50 (e.g., the Tier 1 model component 92) may receive the Tier 1 well measurements 100 to generate a Tier 1 well model. Additionally or alternatively, the interpretation system 50 (e.g., the Tier 1 well model component 92) may interpret the Tier 1 well measurements 100 to generate one or more properties associated with the Tier 1 wells based on the Tier 1 well model. In an embodiment, the interpretation system 50 may store the Tier 1 well model and the one or more properties in the storage component 58. In other embodiments, the interpretation system 50 may transmit the Tier 1 well model to the tuning component 94 for generating a well property model 106.

At block 206, the interpretation system 50 may generate a well property model based on the Tier 1 well model, the Tier 1 well measurements, and a pre-trained model. In some embodiments, the interpretation system 50 (e.g., tuning component 94) may receive the Tier 1 well measurements 110 and the Tier 1 well model from the Tier 1 model component 92. The interpretation system 50 may also retrieve one or more pre-trained models 104 from the storage component 58. The pre-trained models 104 may account for relationships between the Tier 1 well measurements 100 and the Tier 2 well measurements 110 and/or between the Tier 1 well model and the Tier 2 well model. The interpretation system 50 may apply the pre-trained models 104 to the Tier 1 well model to generate the well property model 106 that may predict a particular property of a Tier 2 well based on Tier 2 well measurements 110. In certain instances, the interpretation system 50 may generate multiple well property models 106 that predict different properties of the Tier 2 well. By way example, the interpretation system 50 may generate a first well property model 106 that adjusts for permeability, a second well property model 106 that adjusts for porosity, and/or a third well property model 106 that adjusts for saturation.

At block 208, the interpretation system 50 may receive the Tier 2 well measurements 110. For example, the interpretation system 50 may retrieve the Tier 2 well measurements from the storage component 58. In another example, the interpretation system 50 may receive the Tier 2 well measurements 110 from components positioned within Tier 2 wells in the hydrocarbon site 10 via the communication component 52.

At block 210, the interpretation system 50 may generate a Tier 2 well model based on the Tier 2 well measurements 110. For example, the interpretation system 50 (e.g., the Tier 2 model component 96) may receive and/or retrieve the Tier 2 well measurements 110 to generate the Tier 2 well model. As discussed herein, the Tier 2 well model may be less accurate in comparison to the Tier 1 well model since the Tier 2 well measurements 110 may be less accurate, less complete, and/or less useful for interpretation than the Tier 1 well measurements 100.

At block 212, the interpretation system 50 may generate an adjusted Tier 2 well model based on the Tier 2 well model and the well property model 106. In particular, the interpretation system 50 may apply the well property model 106 to the Tier 2 well model and the Tier 2 well measurements 110 to generate the adjusted Tier 2 well model. For example, the interpretation system 50 may adjust the Tier 2 well model based on the well property model 106 or multiple the well property model 106. The adjusted Tier 2 well model may include an adjusted model for determining an expected set of measurements for a particular property based on Tier 2 well measurements 110. In other words, the adjusted Tier 2 well model may include an enhanced (e.g., adjusted, inferred, transposed) set of measurements associated with the Tier 2 wells.

At block 214, the interpretation system 50 may generate a first predicted set of measurements 152 of the Tier 2 well based on the Tier 2 well model and a second predicted set of measurements 154 of the Tier 2 well based on the adjusted Tier 2 well model. For example, the interpretation system 50 (e.g., the inference component 98) may generate a first predicted set of measurements 152 of the Tier 2 well based on the Tier 2 well model and the Tier 2 well measurements 110. As discussed herein, the Tier 2 well measurements 110 may lack certain types of measurements and the interpretation of Tier 2 well measurements 110 may be difficult and/or inaccurate. With this in mind, the first predicted set of measurements 152 of the Tier 2 well may be inaccurate due to a lack of certain types of measurements and/or the Tier 2 well model being less accurate than the Tier 1 well model. The interpretation system 50 (e.g., the inference component 98) may also generate a second predicted set of measurements 152 corresponding to the Tier 2 well based on the adjusted Tier 2 well model and the Tier 2 well measurements 110.

At block 216, the interpretation system 50 may output the first predicted set of measurements 152 and the second predicted set of measurements 154. For example, the interpretation system 50 (e.g., the inference component 98) may populate a GUI 150 with the first predicted set of measurements 152 associated with the Tier 2 well model and the second predicted set of measurements 154 associated with the adjusted Tier 2 well model for display. As discussed herein, the interpretation system 50 may also populate the GUI 150 with one or more parameters 158, 160 associated with the first predicted set of measurements 152 and adjust the first predicted set of measurements 152 based on adjustments to the one or more parameters 158, 160. As such, the interpretation system 50 may provide various sets of measurements for wells having fewer devices and/or less sophisticated equipment with a high degree of accuracy.

At block 218, the interpretation system 50 may modify well operations based on the first predicted set of measurements 152, the second predicted set of measurements 154, or both. For example, the interpretation system 50 may issue commands to respective devices within the Tier 2 wells to adjust operations based on the analysis gleaned from the predicted set of measurements 152, 154. Additionally or alternatively, the interpretation system 50 may receive an adjustment to one or more parameters 158, 160 to adjust the Tier 2 well model. The interpretation system 50 may generate an adjusted first predicted set of measurements based on the adjustment to the one or more parameters 158, 160 and issue commands to respective devices based on the analysis from the adjusted first predicted set of measurements. As such, the interpretation system 50 may improve drilling and/or production operations with little or no user intervention.

The technical effect of the disclosed embodiments include interpreting measurements (e.g., data) from wells having fewer devices or less sophisticated equipment with a high degree of accuracy while efficiently employing equipment, acquiring additional datasets, and so on. For example, the disclosed embodiments may receive a first set of well measurements from a first set of wells, generate a first well model based on the first set of well measurements, and generate a model based on the first set of well measurements, the first well model, and a pre-trained model. The first set of wells may include sophisticated equipment that generate measurements readily usable for interpretation. Additionally, the disclosed embodiments may receive a second set of well measurements from a second set of wells, generate a second well model based on the second set of well measurements, and determine a first predicted set of measurements of the second set of wells by interpreting the second well model. In contrast, the second set of wells may include less sophisticated equipment and/or less equipment in comparison to the first set of wells. As such, the second well model may not accurately reflect the properties of the second set of wells. The disclosed embodiments may adjust the second well model based on the well property model to generate an enhanced dataset associated with the second set of wells and interpret the adjusted second well model to determine properties of the second set of wells. Such interpretations may be more accurate in comparison to the interpretations of the second well model. In this way, the disclosed embodiments may improve drilling and/or production operations by accurately identifying intervals of interest and/or areas within the wells for perforation.

The foregoing description, for purpose of explanation, has been described with reference to specific embodiments. However, the illustrative discussions above are not intended to be exhaustive or to limit the disclosure to the precise forms disclosed. Many modifications and variations are possible in view of the above teachings. Moreover, the order in which the elements of the methods described herein are illustrated and described may be re-arranged, and/or two or more elements may occur simultaneously. The embodiments were chosen and described in order to best explain the principals of the disclosure and its practical applications, to thereby enable others skilled in the art to best utilize the disclosure and various embodiments with various modifications as are suited to the particular use contemplated.

Finally, the techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under means-plus function. However, for any claims containing elements designated in any other manner, it is intended that such elements are not to be interpreted under means-plus function.

1. A system comprising:
processing circuitry; and
memory storing instructions, wherein the instructions, when executed by the processing circuitry, cause the processing circuitry to:
receive a first set of measurements associated with a first set of wells, wherein the first set of wells is equipped with a first set of measurement tools;
generate a first well model representative of one or more properties associated with the first set of wells, wherein the first well model is generated based on the first set of measurements;
generate a well property model representative of one or more expected properties relative to one or more measurements associated with a well, wherein the well property model is generated based on the first well model and a pre-trained model related to the one or more expected properties;
receive a second set of measurements associated with a second set of wells, wherein the second set of wells is equipped with a second set of measurement tools;
generate a second well model representative of a first set of predicted measurements associated with the second set of wells based on the second set of measurements;
generate an adjusted second well model based on the well property model and the second well model;
determine a second set of predicted measurements associated with the second set of wells based on the adjusted second well model; and
instruct a display to display the first set of predicted measurements and the second set of predicted measurements.

2. The system of claim 1, wherein the first set of measurement tools comprises more equipment than the second set of measurement tools.

3. The system of claim 1, wherein the first set of measurement tools comprises more data points as compared to the second set of measurement tools.

4. The system of claim 1, wherein the pre-trained model is generated based on a machine learning model and a plurality of datasets associated with a plurality of wells, and wherein the machine learning model is configured to identify one or more patterns in the plurality of datasets.

5. The system of claim 1, wherein the instructions, when executed by the processing circuitry, cause the processing circuitry to modify one or more well operations associated with the second set of wells based on the first set of predicted measurements, the second set of predicted measurements, or both.

6. The system of claim 1, wherein the instructions, when executed by the processing circuitry, cause the processing circuitry to:
receive an indication of adjusting at least one parameter associated determining the first set of predicted measurements;
determine an adjusted first set of predicted measurements based on the indication and the second well model; and
instruct the display to display the adjusted first set of predicted measurements, the second set of predicted measurements, or both.

7. The system of claim 6, wherein the instructions, when executed by the processing circuitry, cause the processing circuitry to:
store the adjusted first set of predicted measurements in a storage component; and
update the pre-trained model based on the adjusted first set of predicted measurements.

8. A method comprising:
receiving, via processing circuitry, a first set of measurements associated with a first set of wells from a first set of measurement tools;
generating, via the processing circuitry, a first well model representative of one or more properties associated with the first set of wells, wherein the first well model is generated based on the first set of measurements;
generating, via the processing circuitry, a well property model representative of one or more expected properties relative to one or more measurements associated with a well, wherein the well property model is generated based on the first well model and a pre-trained model related to the one or more expected properties;
receiving, via the processing circuitry, a second set of measurements associated with a second set of wells, wherein the second set of wells is equipped with a second set of measurement tools;
generating, via the processing circuitry, a second well model representative of a first set of predicted measurements associated with the second set of wells based on the second set of measurements;
generating, via the processing circuitry, an adjusted second well model based on the well property model and the second well model;
determining, via the processing circuitry, a second set of predicted measurements associated with the second set of wells based on the adjusted second well model; and
instructing, via the processing circuitry, a display to display the first set of predicted measurements and the second set of predicted measurements.

9. The method of claim 8, comprising modifying, via the processing circuitry, one or more well operations associated with the second set of wells based on the first set of predicted measurements, the second set of predicted measurements, or both.

10. The method of claim 8, comprising training, via the processing circuitry, the pre-trained model using historical data associated with the first set of wells, the second set of wells, or both.

11. The method of claim 10, wherein the pre-trained model is configured to identify one or more patterns in the historical data.

12. The method of claim 8, comprising:
receiving, via the processing circuitry, an indication of adjusting at least one parameter associated determining the first set of predicted measurements;
determining, via the processing circuitry, an adjusted first set of predicted measurements based on the indication and the second well model; and
instructing, via the processing circuitry, the display to display the adjusted first set of predicted measurements, the second set of predicted measurements, or both.

13. The method of claim 8, wherein the first set of measurement tools comprises more data points as compared to the second set of measurement tools.

14. A non-transitory, computer-readable medium comprising instructions that, when executed by a processor, causes the processor to perform operations comprising:
receiving a first set of measurements associated with a first set of wells, wherein the first set of wells is equipped with a first set of measurement tools;
generating a first well model representative of one or more properties associated with the first set of wells, wherein the first well model is generated based on the first set of measurements;
generating a well property model representative of one or more expected properties relative to one or more measurements associated with a well, wherein the well property model is generated based on the first well model and a pre-trained model related to the one or more expected properties;
receiving a second set of measurements associated with a second set of wells, wherein the second set of wells is equipped with a second set of measurement tools;
generating a second well model representative of a first set of predicted measurements associated with the second set of wells based on the second set of measurements;
generating an adjusted second well model based on the well property model and the second well model;
determining a second set of predicted measurements associated with the second set of wells based on the adjusted second well model; and
instructing a display to display the first set of predicted measurements and the second set of predicted measurements.

15. The non-transitory, computer-readable medium of claim 14, wherein the first set of measurement tools comprises more equipment than the second set of measurement tools.

16. The non-transitory, computer-readable medium of claim 14, wherein the pre-trained model is generated based on a machine learning model and a plurality of datasets associated with a plurality of wells, and wherein the machine learning model is configured to identify one or more patterns in the plurality of datasets.

17. The non-transitory, computer-readable medium of claim 14, wherein the instructions, that when executed by the processor, causes the processor to perform operations comprising modifying one or more well operations associated with the second set of wells based on the first set of predicted measurements, the second set of predicted measurements, or both.

18. The non-transitory, computer-readable medium of claim 14, wherein the first set of measurement tools comprises more data points as compared to the second set of measurement tools.

19. The non-transitory, computer-readable medium of claim 14, wherein the instructions, that when executed by the processor, causes the processor to perform operations comprising:
receiving an indication of adjusting at least one parameter associated determining the first set of predicted measurements;
determining an adjusted first set of predicted measurements based on the indication and the second well model; and
instructing the display to display the adjusted first set of predicted measurements, the second set of predicted measurements, or both.

20. The non-transitory, computer-readable medium of claim 14, wherein the instructions, that when executed by the processor, causes the processor to perform operations comprising:
storing the adjusted first set of predicted measurements in a storage component; and
updating the pre-trained model based on the adjusted first set of predicted measurements.
